(19) United States
(12) Patent Application Publication
(10) Pub. No.: US 2012/0122310 A1
(43) Pub. Date: May 17, 2012

(54) METHOD OF MANUFACTURING SEMICONDUCTOR DEVICE

(76) Inventor: Eimei NAKAYAMA, Kawasaki-Shi (JP)

(21) Appl. No.: 13/053,421

(22) Filed: Mar. 22, 2011

(30) Foreign Application Priority Data
Nov. 17, 2010 (JP) 2010-257007

(51) Int. Cl. H01L 21/28

(52) U.S. Cl. 438/593; 257/E21.158

(57) ABSTRACT

In one embodiment, a method of manufacturing a semiconductor device includes forming a first to fourth films over a semiconductor substrate. The method further includes patterning the fourth film to form sparse and dense portions in which patterns of the fourth film are sparse and dense, respectively, and etching the third film by using the patterns of the fourth film as a mask. The method further includes etching the third film by using the patterns of the third and fourth films as a mask so as to expose the first film between the patterns in the sparse portion, and so as to partially remove the second film between the patterns in the dense portion so that the second film between the patterns remains. The method further includes forming a fifth film on the first film exposed in the sparse portion to have a first thickness, and on the second film remaining in the dense portion to have a second thickness smaller than the first thickness by using a C_{X}F_{Y}H_{Z} gas, where X, Y, and Z are integers of zero or more and satisfy 0<Y<2X and 0≦Z≦4. The method further includes etching the fifth film and the second film remaining between the patterns in the dense portion so as to expose the first film between the patterns in the dense portion, and then removing the remaining fifth film.

### CROSS REFERENCE TO RELATED APPLICATION

This application is based upon and claims the benefit of priority from the prior Japanese Patent Application No. 2010-257007, filed on Nov. 17, 2010, the entire contents of which are incorporated herein by reference.

### FIELD

Embodiments described herein relate to a method of manufacturing a semiconductor device.

### BACKGROUND

In a recent interconnect forming process for a semiconductor device, an etching of an interconnect layer has been mainly performed by using a hard mask made of silicon nitride or silicon oxide. The hard mask is formed, for example, by forming a hard mask material and a resist film sequentially on the interconnect layer as an underlying film, patterning the resist film, and dry-etching the hard mask material by using the resist film as a mask. The dry etching is performed by exciting plasma by using a gas containing CHF₃ and CF₄, for example.

Also, due to a recent trend of miniaturization and high integration of the semiconductor device, an etching with good shape controllability has been required even in a case where mask patterns includes sparse patterns and dense patterns. However, in a case where the above mentioned gas is used, a difference of etching shapes is caused between a portion where the patterns are sparse (sparse portion) and a portion where the patterns are dense (dense portion).

In the dry etching by using the above gas, radical species represented by C_{A}F_{B} (where A and B are integers of one or more) are generated in the plasma, and react with the silicon nitride or the silicon oxide of the hard mask material. As a result, a reaction product such as SiF₄ is vaporized and desorbed, which accelerates the etching. However, since the width of trenches between the patterns is narrow in the dense portion, the radical species do not easily go into those trenches, so that the etching rate of the hard mask material becomes low in the dense portion. On the other hand, since the width of trenches between the patterns is wide in the sparse portion, the radical species easily go into those trenches, so that the etching rate of the hard mask material becomes high in the sparse portion.

As a result, the etching amount of the interconnect layer (underlying film) in the trenches is large in the sparse portion. On the other hand, the etching amount of the interconnect layer in the trenches is small in the dense portion. Therefore, when the interconnect layer is etched by using the hard mask, there is a problem that a substrate which should not be etched is etched in the sparse portion, or the interconnect layer which should be etched and removed remains in the dense portion.

### BRIEF DESCRIPTION OF THE DRAWINGS

FIGS. 1 to 9 are side sectional views showing a method of manufacturing a semiconductor device according to an embodiment of the disclosure;

FIG. 10 is a graph showing Y/X values of various C_{X}F_{Y}H_{Z} gases;

FIGS. 11A and 11B are side sectional views for explaining an application of the method of manufacturing the semiconductor device according to the present embodiment;

FIG. 12 is a schematic side sectional view for explaining an etching suppression effect of a fifth film formed by using an F-rich C_{X}F_{Y}H_{Z} gas;

FIG. 13 is a schematic side sectional view for explaining the etching suppression effect of the fifth film formed by using a C-rich C_{X}F_{Y}H_{Z} gas; and

FIGS. 14A and 14B are side sectional views for explaining modifications of the method of manufacturing the semiconductor device according to the present embodiment.

### DETAILED DESCRIPTION

Embodiments will now be explained with reference to the accompanying drawings.

An embodiment described herein is a method of manufacturing a semiconductor device on a semiconductor substrate, the method including forming a first film over the semiconductor substrate, a second film on the first film, a third film on the second film, and a fourth film on the third film. The method further includes patterning the fourth film to form a sparse portion in which patterns of the fourth film are sparse and a dense portion in which the patterns of the fourth film are dense. The method further includes etching the third film by using the patterns of the fourth film as a mask. The method further includes etching the second film by using the patterns of the third and fourth films as a mask so as to expose the first film between the patterns in the sparse portion, and so as to partially remove the second film between the patterns in the dense portion so that the second film between the patterns remains. The method further includes forming a fifth film on the first film exposed in the sparse portion to have a first thickness, and on the second film remaining in the dense portion to have a second thickness smaller than the first thickness by using a C_{X}F_{Y}H_{Z} gas, where X, Y, and Z are integers of zero or more and satisfy 0<Y<2X and 0≦Z≦4. The method further includes etching the fifth film and the second film remaining between the patterns in the dense portion so as to expose the first film between the patterns in the dense portion. The method further includes removing the fifth film remaining after the etching of the second film between the patterns in the dense portion.

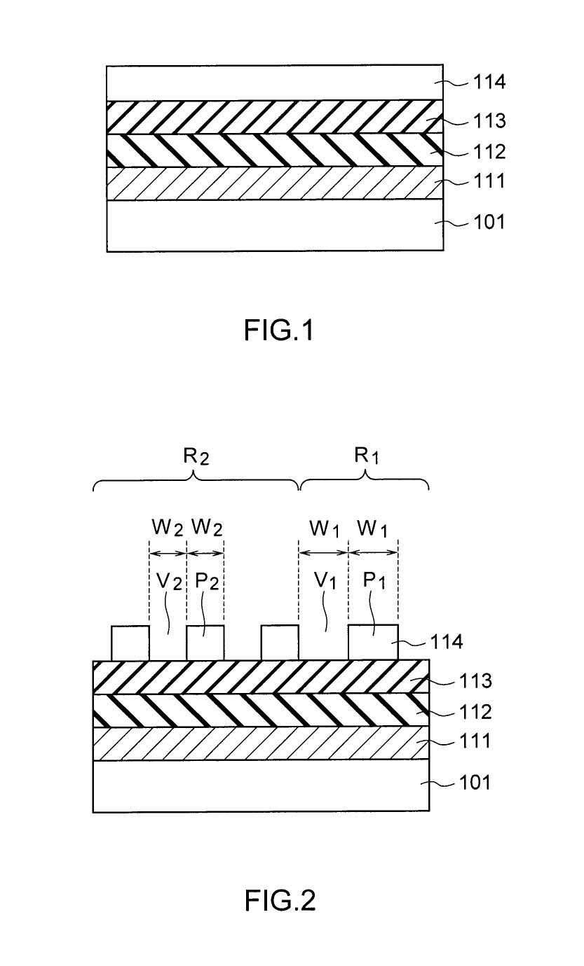

FIGS. 1 to 9 are side sectional views showing a method of manufacturing a semiconductor device according to an embodiment of the disclosure.

First, as shown in FIG. 1, a polysilicon film 111 as an underlying film is formed over a substrate 101. The polysilicon film 111 is an example of a first film of the disclosure. The thickness of the polysilicon film 111 is herein 150 nm. The substrate 101 is a semiconductor substrate such as a silicon substrate, for example.

Next, as shown in FIG. 1, a silicon nitride film 112 as a first hard mask material, a silicon oxide film 113 as a second hard mask material, and a resist film 114 are sequentially formed on the polysilicon film 111. The silicon nitride film 112, the silicon oxide film 113, and the resist film 114 are examples of second, third, and fourth films of the disclosure. The silicon nitride film 112 is formed by reduced pressure chemical vapor deposition (reduced pressure CVD), for example. The thickness of the silicon nitride film 112 is herein approximately 200 nm. Also, the thickness of the resist film 114 is herein approximately 100 nm.

Next, as shown in FIG. 2, the resist film 114 is patterned by lithography to form a sparse portion R₁ in which patterns of the resist film 114 are sparse and a dense portion R₂ in which the patterns of the resist film 114 are dense.

In FIG. 2, a pattern of the resist film 114 in the sparse portion R₁ is expressed by P₁, and patterns of the resist film 114 in the dense portion R₂ are expressed by P₂. Also, FIG. 2 shows trenches between the patterns P₁ and P₂. In FIG. 2, a trench between the patterns in the sparse portion R₁ is expressed by V₁, and trenches between the patterns in the dense portion R₂ are expressed by V₂.

In the present embodiment, the patterns of the resist film 114 form a line pattern in which each of the patterns has a linear planar shape. The patterns of the resist film 114 have a predetermined line width and a predetermined space width in each of the sparse and dense portions R₁ and R₂. Also, in the present embodiment, the line width and the space width are set to the same value in each of the sparse and dense portions R₁ and R₂. In FIG. 2, the line width and the space width in the sparse portion R₁ are expressed by W₁, and the line width and the space width in the dense portion R₂ are expressed by W₂.

In the present embodiment, the widths W₁ and W₂ are set to satisfy the relationship of W₁>W₂, so that the region R₁ becomes a sparse portion and the region R₂ becomes a dense portion. In the present embodiment, the width W₁ is set to be 200 nm or more while the width W₂ is set to be 200 nm or less. Meanwhile, in each of the sparse portion R₁ and the dense portion R₂, the line width and the space width may be set to have different values.

Also, in the present embodiment, the patterns P₂ in the dense portion R₂ are massed patterns including plural patterns, and are formed to be parallel to one another. As shown in FIG. 2, the space width W₂ in the dense portion R₂ is a distance between the adjacent patterns P₂. On the other hand, the pattern P₁ in the sparse portion R₁ is an isolated pattern including one pattern, and is formed to be parallel to the patterns P₂ in the dense portion R₂. As shown in FIG. 2, the space width W₁ in the sparse portion R₁ is a distance between the pattern P₁ and a pattern P₂ adjacent to the pattern P₁.

The sparse portion R₁ may include massed patterns including plural patterns similarly to the dense portion R₂.

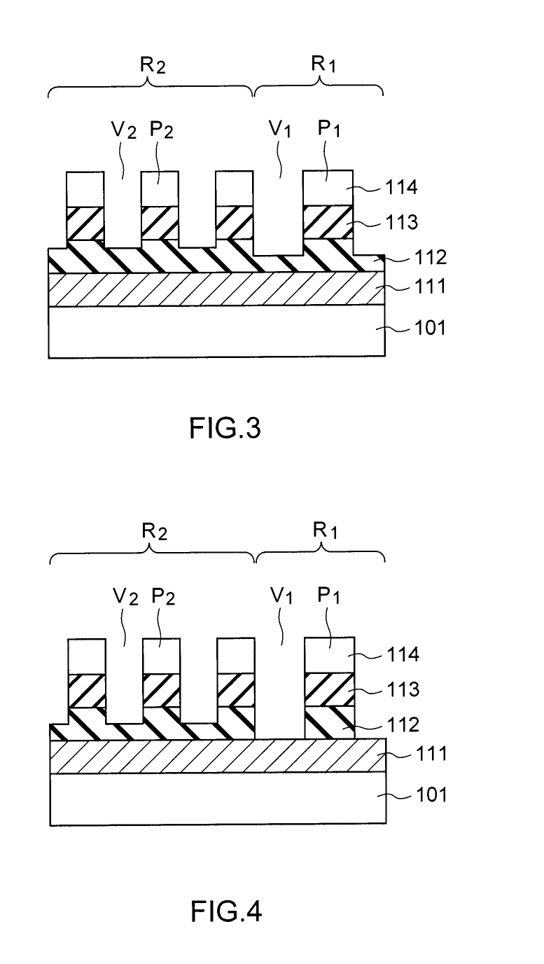

Next, as shown in FIG. 3, a dry etching using the patterns of the resist film 114 as a mask is performed to remove the silicon oxide film 113 in the trenches V₁ and V₂. Subsequently, as shown in FIG. 4, a dry etching using the patterns of the resist film 114 and the silicon oxide film 113 as a mask is performed to remove the silicon nitride film 112 in the trenches V₁ and V₂. The etching conditions for these dry etchings are as follows.
Plasma apparatus to be used: Parallel flat plate type reactive plasma etching apparatus
Etching gas to be used (the flow rate is shown in the brackets): Mixed gas containing the following gas
   CHF₃ gas (225 sccm)
   CF₄ gas (45 sccm)
   Ar gas (537 sccm)
   O₂ gas (26 sccm)
Source power: 600 W (100 MHz)
Bias power: 300 W (13.56 MHz)
Pressure: 40 mT

In the etchings in FIGS. 3 and 4, radical species dissociated and generated in the plasma go into the trenches V₁ and V₂ to accelerate the etchings. However, since the space width W₂ is small in the dense portion R₂, the radical species do not easily go into the trenches V₂, and the etching rate of the silicon oxide film 113 and the silicon nitride film 112 is low. On the other hand, since the space width W₁ is large in the sparse portion R₁, the radical species easily go into the trench V₁, and the etching rate of the silicon oxide film 113 and the silicon nitride film 112 is high.

Consequently, as shown in FIG. 3, at the time immediately after the etching of the silicon oxide film 113 in the trenches V₁ and V₂ is completed, the etching amount of the silicon nitride film 112 in the trench V₁ is large while the etching amount of the silicon nitride film 112 in the trenches V₂ is small. In other words, a difference in etching amount of the silicon nitride film 112 is caused between the sparse portion R₁ and the dense portion R₂. This difference in etching amount becomes larger through the etching in FIG. 4.

Accordingly, when the etching in FIG. 4 is performed until the trenches V₂ reach the polysilicon film 111, the polysilicon film 111 in the trench V₁ is over-etched largely. Such an over-etching becomes a cause that the polysilicon film 111 remains in the trenches V₂ and a cause that the substrate 101 is etched in the trench V₁, when the etching of the polysilicon film 111 is performed as described later.

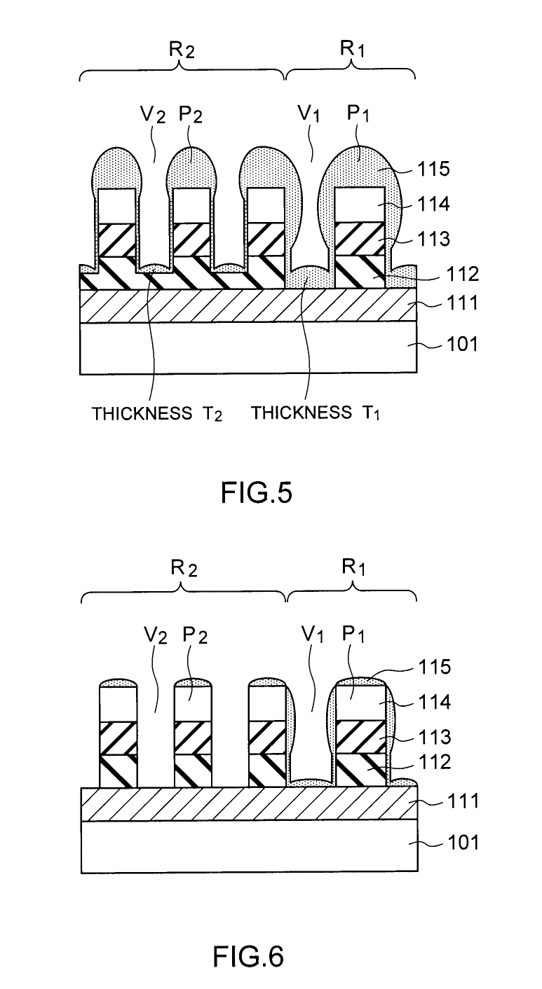

Therefore, in the present embodiment, the etching in FIG. 4 is performed until the trench V₁ reaches the polysilicon film 111. Therefore, as shown in FIG. 4, the silicon nitride film 112 in the trench V₁ is removed from the sparse portion R₁ so as to expose the polysilicon film 111 in the trench V₁, and the silicon nitride film 112 in the trenches V₂ is partially removed from the dense portion R₂ so that the silicon nitride film 112 in the trenches V₂ remains. This makes it possible to suppress the over-etching of the polysilicon film 111 in the trench V₁. As described later, the silicon nitride film 112 remaining in the trenches V₂ is removed in the processes of FIGS. 5 and 6.

It is preferred to finish the etching in FIG. 4 immediately after the trench V₁ has reached the polysilicon film 111 so that the etching amount (over-etching amount) of the polysilicon film 111 in the trench V₁ becomes small.

Next, as shown in FIG. 5, a CF polymer film 115 is formed on the sparse and dense portions R₁ and R₂. The CF polymer film 115 is a polymer film containing carbon (C) and fluorine (F) as constituent elements. The CF polymer film 115 is an example of a fifth film of the disclosure. An example of the CF polymer film 115 is a fluorocarbon film.

The CF polymer film 115 is attached to the upper surfaces and the side surfaces of the mask (112, 113 and 114) and the bottom surfaces of the trenches V₁ and V₂ in the sparse and dense portions R₁ and R₂. In the trench V₁, the CF polymer film 115 as thick as portions of the CF polymer film 115 on the upper surfaces of the mask is attached to the bottom surface of the trench V₁. On the other hand, in the trenches V₂, the CF polymer film 115 that is very thin compared with the portions of the CF polymer film 115 on the upper surfaces of the mask is attached to the bottom surfaces of the trenches V₂.

In FIG. 5, a thickness of the CF polymer film 115 formed on the bottom surface of the trench V₁ is expressed by T₁, and a thickness of the CF polymer film 115 formed on the bottom surfaces of the trenches V₂ is expressed by T₂. These thicknesses T₁ and T₂ satisfy the relationship of T₁>T₂, more specifically, the relationship T₁>>T₂. The thicknesses T₁ and T₂ are examples of first and second thicknesses of the disclosure, respectively.

In this manner, the CF polymer film 115 is formed on the polysilicon film 111 exposed in the sparse portion R₁ to have the thickness T₁, and is formed on the silicon nitride film 112 remaining in the dense portion R₂ to have the thickness T₂ smaller than the thickness T₁. In the present embodiment, the thickness T₂ becomes much smaller than the thickness T₁. The reason why the CF polymer film 115 is formed in such a manner will be described later.

Also, in the present embodiment, the CF polymer film 115 is formed by using a C_{X}F_{Y}H_{Z} gas, where C, F and H represent carbon, fluorine and hydrogen, respectively. In addition, X, Y and Z are integers of zero or more, and satisfy conditions of 0<Y<2X and 0≦Z≦4. Examples of the C_{X}F_{Y}H_{Z} gas that can be used in the present embodiment are a C₄F₆ gas, a C₅F₈ gas, and a CH₃F gas.

The CF polymer film 115 can be formed by an apparatus and conditions similar to those in the case of the dry etching. In the present embodiment, the CF polymer film 115 is formed under the following conditions.
Plasma apparatus to be used: Parallel flat plate type reactive plasma etching apparatus
Gas to be used (the flow rate is shown in the brackets): Mixed gas containing the following gas
   C₄F₆ gas (20 sccm)
   Ar gas (406 sccm)
   O₂ gas (14 sccm)
Source power: 300 W (100 MHz)
Bias power: 1500 W (13.56 MHz)
Pressure: 20 mT

In this manner, in the present embodiment, the CF polymer film 115 is formed by using the C₄F₆ gas which is an example of C_{X}F_{Y}H₂ gas, the Ar gas, and the O₂ gas. The mixed gas may contain two or more kinds of C_{X}F_{Y}H₂ gases.

When the CF polymer film 115 is formed, radical species dissociated and generated in the plasma go into the trenches V₁ and V₂ to accelerate the formation of the CF polymer film 115, similarly to the etchings in FIGS. 3 and 4. However, since the space width W₂ is small in the dense portion R₂, the radical species do not easily go into the trenches V₂, so that the CF polymer film 115 is not easily attached to the bottom surfaces of the trenches V₂. On the other hand, since the space width W₁ is large in the sparse portion R₁, the radical species easily go into the trench V₁, so that the CF polymer film 115 is easily attached to the bottom surface of the trench V₁.

Accordingly, the CF polymer film 115 is formed on the polysilicon film 111 exposed in the sparse portion R₁ to have the thickness T₁, and is formed on the silicon nitride film 112 remaining in the dense portion R₂ to have the thickness T₂ smaller than the thickness T₁. In the present embodiment, the difference between the space width W₁ and the space width W₂ is large, so that the thickness T₂ becomes much smaller than the thickness T₁.

Next, as shown in FIG. 6, a dry etching using the silicon oxide film 113, the resist film 114, and the CF polymer film 115 as a mask is performed to etch the CF polymer film 115 and the silicon nitride film 112 remaining in the trenches V₂ so as to expose the polysilicon film 111 in the trenches V₂. In this dry etching, the CF polymer film 115 functions as a protective mask for protecting the polysilicon film 111 in the trench V₁ from being etched. This dry etching is performed under the same etching conditions as those of the dry etchings in FIGS. 3 and 4.

Before the etching in FIG. 6 is started, the CF polymer film 115 as thick as portions of the CF polymer film 115 on the upper surfaces of the mask (113, 114, 115) is attached to the bottom surface of the trench V₁, and the CF polymer film 115 that is very thin compared with the portions of the CF polymer film 115 on the upper surfaces of the mask is attached to the bottom surfaces of the trenches V₂ (refer to FIG. 5).

Accordingly, when the etching in FIG. 6 is started, the CF polymer film 115 on the bottom surfaces of the trenches V₂ is removed immediately, so that the silicon nitride film 112 is exposed in the trenches V₂. Then, in the etching in FIG. 6, the etching of the silicon nitride film 112 exposed in the trenches V₂ and the etching of the CF polymer film 115 remaining in the trench V₁ are performed simultaneously. The etching in FIG. 6 is continued until the silicon nitride film 112 in the trenches V₂ is removed and the polysilicon film 111 is exposed in the trenches V₂.

If the etching in FIG. 6 is performed in a state where no CF polymer film 115 is attached to the trenches V₂, an over-etching of the polysilicon film 111 in the trench V₁ will be caused simultaneously with the etching of the silicon nitride film 112 in the trenches V₂. Therefore, it is understood that the CF polymer film 115 in the trench V₁ has an effect of suppressing the over-etching of the polysilicon film 111 in the trench V₁, and lowering the difference in etching amount of the polysilicon film 111 between the sparse portion R₁ and the dense portion R₂.

In the etching in FIG. 6, the CF polymer film 115 preferably remains on the bottom surface of the trench V₁ until the trenches V₂ reach the polysilicon film 111. Consequently, the effect of suppressing the over-etching of the polysilicon film 111 in the trench V₁ is maintained from the beginning to the end of the etching in FIG. 6. Such a CF polymer film 115 can be formed by setting the thickness T₁ to be sufficiently larger than the thickness T₂ in the process in FIG. 5, for example.

Also, the CF polymer film 115 is preferably formed in the process of FIG. 5 so that the portions of the CF polymer film 115 on the mask in the dense portion R₂ are not contact one another. The reason for this is that if these portions contact one another, the openings of the trenches V₂ are closed by the CF polymer film 115. This makes it difficult to etch the silicon nitride film 112 in the trenches V₂ at the time of the etching in FIG. 6.

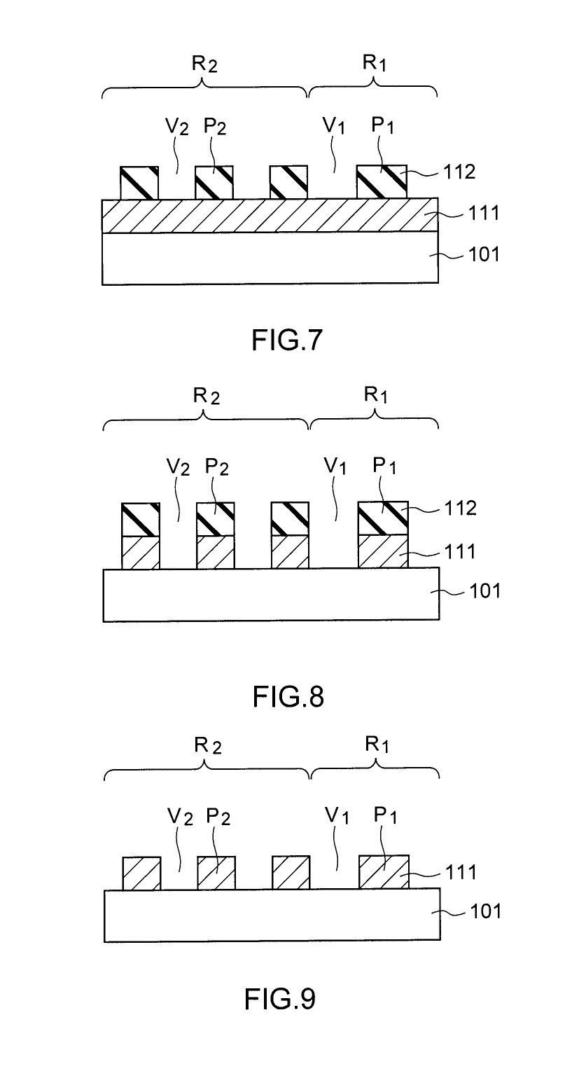

Next, as shown in FIG. 7, after the removal of the CF polymer film 115 and the silicon nitride film 112 in the trenches V₂, the silicon oxide film 113, the resist film 114, and the remaining CF polymer film 115 in the sparse and dense portions R₁ and R₂ are removed. The CF polymer film 115 can be removed by a process using an O₂ gas, for example. Similarly, the resist film 114 and the silicon oxide film 113 can be removed by a process using an O₂ gas. FIG. 7 shows a state where a hard mask for etching the polysilicon film 111 has been formed by the silicon nitride film 112.

Next, as shown in FIG. 8, after the removal of the silicon oxide film 113, the resist film 114, and the CF polymer film 115, the polysilicon film 111 is etched by using the silicon nitride film 112 as a mask. The etching is performed by RIE (Reactive Ion Etching), for example.

Next, as shown in FIG. 9, after the etching of the polysilicon film 111, the silicon nitride film 112 is removed. In such a manner, the etching of the polysilicon film 111 is completed.

As described above, in the present embodiment, as shown in FIG. 4, the etching of the silicon nitride film 112 is performed until the trench V₁ reaches the polysilicon film 111, so that the silicon nitride film 112 in the trench V₁ is removed from the sparse portion R₁ so as to expose the polysilicon film 111 in the trench V₁, and the silicon nitride film 112 in the trenches V₂ is partially removed from the dense portion R₂ so that the silicon nitride film 112 in the trenches V₂ remains.

Also, as shown in FIG. 5, the CF polymer film 115 is formed on the polysilicon film 111 exposed in the trench V₁ to have the thickness T₁, and is formed on the silicon nitride film 112 remaining in the trenches V₂ to have the thickness T₂ smaller than the thickness T₁, by using the C_{X}F_{Y}H_{Z} gas.

Further, as shown in FIG. 6, the etching by using the silicon oxide film 113, the resist film 114, and the CF polymer film 115 as a mask is performed to etch the CF polymer film 115 and the silicon nitride film 112 remaining in the trenches V₂ so as to expose the polysilicon film 111 in the trenches V₂.

Consequently, in the present embodiment, the over-etching of the polysilicon film 111 in the trench V₁ can be suppressed, and the difference in etching amount of the polysilicon film 111 between the sparse portion R₁ and the dense portion R₂ can be lowered. Therefore, according to the present embodiment, interconnect patterns with high dimensional accuracy can be formed by using the polysilicon film 111 as an interconnect layer.

### (Details of C_{X}F_{Y}H_{Z} Gas)

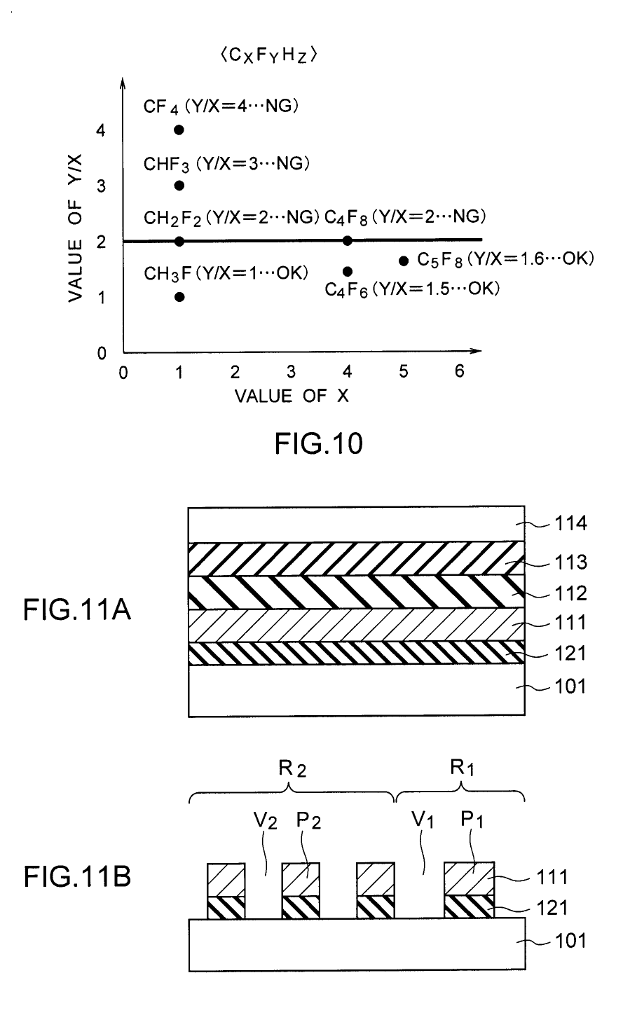

Hereinafter, details of the C_{X}F_{Y}H_{Z} gas will be described with reference to FIG. 10. FIG. 10 is a graph showing Y/X values of various C_{X}F_{Y}H_{Z} gases. The horizontal axis of FIG. 10 represents an X value while the vertical axis of FIG. 10 represents an Y/X value.

As described above, the C_{X}F_{Y}H_{Z} gas is used to form the CF polymer film (fifth film) 115 in the process in FIG. 5. Here, C, F, and H represent carbon, fluorine, and hydrogen, respectively. Also, X, Y, and Z are integers of zero or more and satisfy conditions of 0<Y<2X and 0≦Z≦4.

FIG. 10 shows a C₄F₆ gas, a C₅F₈ gas, and a CH₃F gas as examples of the C_{X}F_{Y}H_{Z} gas that satisfies the conditions of 0<Y<2X and 0≦Z≦4, and shows a C₄F₈ gas, a CH₂F₂ gas, a CHF₃ gas, and a CF₄ gas as examples of the C_{X}F_{Y}H_{Z} gas that does not satisfy the conditions of 0<Y<2X and 0≦Z≦4.

The significance of the conditions of 0<Y<2X and 0≦Z≦4 will be described below.

First, the condition of X>0 indicates that a constituent molecule of the C_{X}F_{Y}H_{Z} gas contain a C atom. The C atom has a characteristic that it is attached to a film containing Si (silicon) atoms such as the polysilicon film, the silicon nitride film, or the silicon oxide film at a high rate. Accordingly, using the C_{X}F_{Y}H_{Z} gas that satisfies the condition of X>0 in the process in FIG. 5 is advantageous in that the fifth film 115 can be formed by a general method of forming a film such as CVD. In a case where the general method such as CVD can be adopted, the process in FIG. 5 can be performed within the same chamber in which the processes in FIGS. 1 to 4 are performed without bringing out the substrate 101 from the chamber.

Also, the condition of Y>0 indicates that a constituent molecule of the C_{X}F_{Y}H_{Z} gas contain an F atom. This means that examples of the C_{X}F_{Y}H_{Z} gas can include a gas containing only a C atom and an F atom, but does not include a gas containing only a C atom and an H atom such as a CH₄ gas. According to experiments by the present inventors, the fifth film 115 formed by using the C_{X}F_{Y}H_{Z} gas containing no F atom has poorer film quality than the fifth film 115 formed by using the C_{X}F_{Y}H_{Z} gas containing an F atom. Furthermore, according to the experiments by the present inventors, using the CH₄ gas causes a problem that pipes of the chamber are clogged due to the extremely high attachment rate of the CH₄. Therefore, the C_{X}F_{Y}H_{Z} gas to be used in the present embodiment is limited to one that satisfies the condition of Y>0.

Also, the C_{X}F_{Y}H_{Z} gas used in the present embodiment satisfies the condition of Y<2X. Hereinafter, the C_{X}F_{Y}H_{Z} gas that satisfies the condition of Y<2X is referred to as a “C-rich C_{X}F_{Y}H_{Z} gas”, meaning that it contains a large amount of C atoms. On the other hand, the C_{X}F_{Y}H_{Z} gas that satisfies the condition of Y 2X is referred to as an “F-rich C_{X}F_{Y}H_{Z} gas”, meaning that it contains a large amount of F atoms. Accordingly, the C_{X}F_{Y}H_{Z} gas used in the present embodiment can be referred to as a C-rich C_{X}F_{Y}H_{Z} gas.

As described above, the C atom has a characteristic that it is attached to the film containing silicon atoms at a high rate.

Accordingly, the C-rich C_{X}F_{Y}H_{Z} gas has an advantage that it causes the fifth film 115 to be easily attached the polysilicon film 111, the silicon nitride film 112, and the silicon oxide film 113 than the F-rich C_{X}F_{Y}H_{Z} gas. Consequently, forming the fifth film 115 by using the C-rich C_{X}F_{Y}H_{Z} gas enables the over-etching of the polysilicon film 111 in the trench V₁ to be suppressed effectively at the time of the etching in FIG. 6.

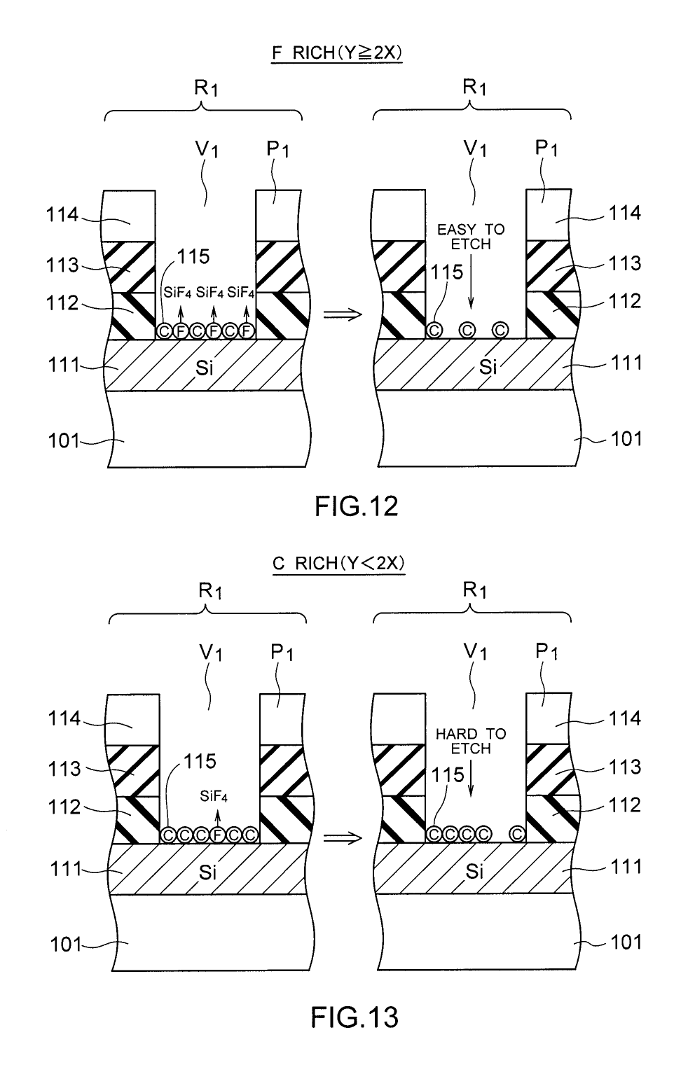

This will be described in details with reference to FIGS. 12 and 13. FIG. 12 is a schematic side sectional view for explaining the etching suppression effect of the fifth film 115 formed by using the F-rich C_{X}F_{Y}H_{Z} gas. FIG. 13 is a schematic side sectional view for explaining the etching suppression effect of the fifth film 115 formed by using the C-rich C_{X}F_{Y}H_{Z} gas.

FIGS. 12 and 13 schematically show the fifth film 115 which is formed on the polysilicon film 111 in the trench V₁ in the process in FIG. 5. Each circled C and circled F represents a C atom and an F atom included in the fifth film 115. Among these C atoms and F atoms, the F atoms react with the polysilicon film 111, and are vaporized and desorbed as SiF₄, as shown in FIGS. 12 and 13. This is the reason why the F atoms have lower attachment rate to the film containing silicon atoms, compared with the C atom.

As shown in FIG. 12, the fifth film 115 formed by the F-rich C_{X}F_{Y}H_{Z} gas contains relatively many F atoms. For this reason, the fifth film 115 in FIG. 12 is not easily attached to the polysilicon film 111 in the trench V₁. Consequently, if the fifth film 115 is formed by using the F-rich C_{X}F_{Y}H_{Z} gas, the over-etching of the polysilicon film 111 in the trench V₁ cannot be suppressed effectively at the time of the etching in FIG. 6.

On the other hand, as shown in FIG. 13, the fifth film 115 formed by the C-rich C_{X}F_{Y}H_{Z} gas contains relatively many C atoms. For this reason, the fifth film 115 in FIG. 13 is easily attached to the polysilicon film 111 in the trench V₁. Consequently, if the fifth film 115 is formed by using the C-rich C_{X}F_{Y}H_{Z} gas, the over-etching of the polysilicon film 111 in the trench V₁ can be suppressed effectively at the time of the etching in FIG. 6.

Also, the C_{X}F_{Y}H_{Z} gas used in the present embodiment satisfies the condition of 0≦Z≦4. The condition of Z≧0 has an effect of decreasing the ratio of F atoms contained in the C_{X}F_{Y}H_{Z} gas, so that the C_{X}F_{Y}H_{Z} gas is made C-rich. The condition of Z≦4 has an effect of suppressing the ratio of H atoms contained in the C_{X}F_{Y}H_{Z} gas, so that the C_{X}F_{Y}H_{Z} gas is mostly formed by C atoms and F atoms in a case where the X value is large.

For example, in a case where the C_{X}F_{Y}H_{Z} molecules are entirely single-bonded, the relationship of 2X+2=Y+Z is satisfied among X, Y and Z. When the simultaneous equations of 2X+2=Y+Z and Y<2X are solved, a condition of Z>2 (i.e., Z≧3) is derived. Accordingly, in a case where the C_{X}F_{Y}H_{Z} molecules are entirely single-bonded, the Z value is limited to 3 or 4.

Meanwhile, the C_{X}F_{Y}H_{Z} gas used in the present embodiment may or may not contain an H atom as is understood from the condition of Z≧0. Also, the C_{X}F_{Y}H_{Z} molecule may or may not contain a double bond and/or a triple bond.

As described above, in the present embodiment, the fifth film (CF polymer film) 115 is formed by using the C_{X}F_{Y}H_{Z} gas that satisfies the conditions of 0<Y<2X and 0≦Z≦4 in the process in FIG. 5. This can provide the present embodiment with advantages that the fifth film 115 is easily formed, the fifth film 115 having good quality can be formed, and the like. This also makes it possible to effectively suppress the over-etching of the polysilicon film 111 in the trench V₁ at the time of the etching in FIG. 6.

### (Example of Using Polysilicon Film 111)

FIGS. 11A and 11B are side sectional views for explaining an application of the method of manufacturing the semiconductor device according to the present embodiment. FIGS. 11A and 11B show an example of using the polysilicon film 111 shown in FIGS. 1 to 9.

FIG. 11A is a side sectional view corresponding to FIG. 1. In the present application, as shown in FIG. 11A, the polysilicon film 111 is formed on the substrate 101 via an insulating film 121. The insulating film 121 is a silicon oxide film, for example.

FIG. 11B is a side sectional view corresponding to FIG. 9. In the present application, as shown in FIG. 11B, patterns P₁ and P₂ of the polysilicon film 111 are formed on the substrate 101 via the insulating film 121.

The patterns P₁ and P₂ in FIG. 11B can be used as MOSFETs, for example. In this case, the insulating film 121 and the polysilicon film 111 shown in FIG. 11B are used as gate insulators and gate electrodes of the MOSFETs, respectively.

On the other hand, each of the patterns P₂ in FIG. 11B can be used to form a memory cell transistor including a gate insulator, a floating gate (first gate electrode), an inter-gate insulator, and a control gate (second gate electrode). In this case, the insulating film 121 and the polysilicon film 111 shown in FIG. 11B are used as the gate insulator and the floating gate of each memory cell transistor, respectively.

Also, the pattern P₁ in FIG. 11B can be used to form a select transistor including a gate insulator and a gate electrode. In this case, the insulating film 121 shown in FIG. 11B is used as the gate insulator of the select transistor, and the polysilicon film 111 shown in FIG. 11B is used as a part of the gate electrode of the select transistor.

More specifically, the gate electrode of the select transistor includes a first electrode layer, an inter-gate insulator, and a second electrode layer formed sequentially on the substrate, and the first and the second electrode layers are electrically connected through an opening formed in the inter-gate insulator. The polysilicon film 111 shown in FIG. 11B is used as the first electrode layer.

In the present application, the polysilicon film 111 is used as an electrode material to form gate electrodes. However, the application of the polysilicon film 111 is not limited to the electrode material. The polysilicon film 111 may be used as an interconnect layer for forming a multi-layer interconnect structure, for example. Also, the polysilicon film 111 may be replaced with a metal film or a multi-layer film including a polysilicon film and a metal film. The polysilicon film 111 may be replaced with a semiconductor film or a conductive film.

Also, the silicon nitride film 112 shown in FIGS. 1 to 9 may be replaced with another insulating film (e.g., a silicon oxynitride film) or a multi-layer insulating film including a silicon nitride film.

Similarly, the silicon oxide film 113 shown in FIGS. 1 to 9 may be replaced with another insulating film or a multi-layer insulating film including a silicon oxide film.

### (Modification of Conditions for Forming CF Polymer Film 115)

Hereinafter, a modification of the conditions for forming the CF polymer film 115 is shown. In the present embodiment, the CF polymer film 115 may be formed under the following conditions.
Plasma apparatus to be used: Parallel flat plate type reactive plasma etching apparatus
Gas to be used (the flow rate is shown in the brackets): Mixed gas containing the following gas
   C₅F₈ gas (20 sccm)
   Ar gas (400 sccm)
   O₂ gas (5 sccm)
Source power: 300 W (100 MHz)
Bias power: 3500 W (13.56 MHz)
Pressure: 20 mT

In this manner, in the present modification, the CF polymer film 115 is formed by using the C₅F₈ gas which is an example of the C_{X}F_{Y}H_{Z} gas, the Ar gas, and the O₂ gas. Meanwhile, the mixed gas may contain two or more kinds of C_{X}F_{Y}H_{Z} gases.

### (Modifications of Processes in FIGS. 1 to 9)

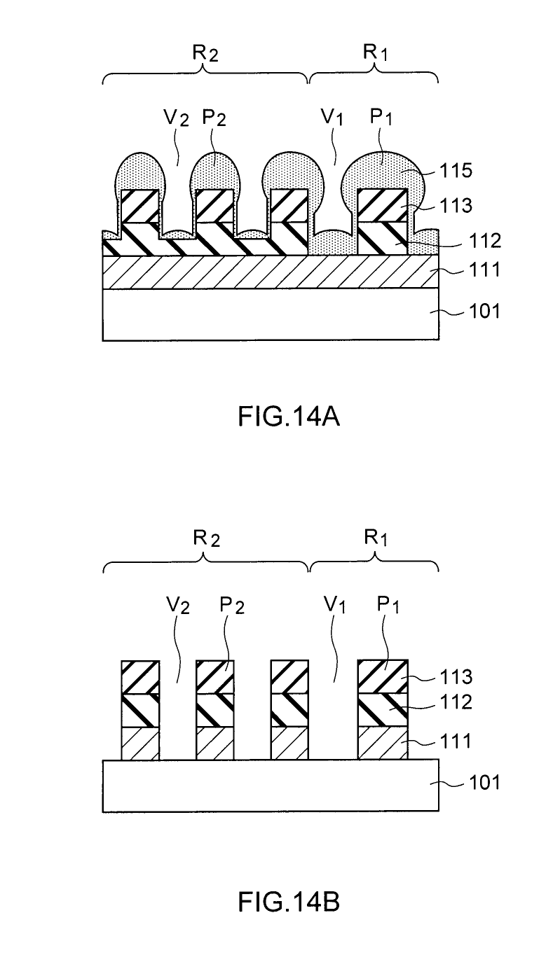

FIGS. 14A and 14B are side sectional views for explaining modifications of the method of manufacturing the semiconductor device according to the present embodiment.

In the process in FIG. 3, the resist film 114 may be removed after the removal of the silicon oxide film 113 in the trenches V₁ and V₂. In this case, in the process in FIG. 4, a dry etching using the silicon oxide film 113 as a mask is performed to remove the silicon nitride film 112 in the trenches V₁ and V₂. Also, in the process in FIG. 5, the CF polymer film 115 is formed on the polysilicon film 111, the silicon nitride film 112, and the silicon oxide film 113. An example of the CF polymer film 115 formed in such a manner is shown in FIG. 14A. The processes after FIG. 14A can be performed in a similar manner to that of the processes in FIGS. 6 to 9.

On the other hand, in the process in FIG. 7, only the resist film 114 and the CF polymer film 115 may be removed so that the silicon nitride film 112 and the silicon oxide film 113 remain. In this case, in the process in FIG. 8, the polysilicon film 111 is etched by using the silicon nitride film 112 and the silicon oxide film 113 as a mask. An example of the polysilicon film 111 etched in such a manner is shown in FIG. 14B. The process after FIG. 14B can be performed in a similar manner to that of the process in FIG. 9.

In the case of adopting the process in FIG. 14A, the silicon oxide film 113 and the CF polymer film 115 may be removed so that the silicon nitride film 112 remains in the process in FIG. 7, or only the CF polymer film 115 may be removed so that the silicon nitride film 112 and the silicon oxide film 113 remain in the process in FIG. 7.

Finally, effects of the present embodiment will be described.

As described above, in the present embodiment, as shown in FIG. 4, the etching of the silicon nitride film 112 is performed until the trench V₁ reaches the polysilicon film 111, so that the silicon nitride film 112 in the trench V₁ is removed so as to expose the polysilicon film 111 in the sparse portion R₁, and the silicon nitride film 112 in the trenches V₂ is partially removed so that the silicon nitride film 112 in the dense portion R₂ remain.

Also, as shown in FIG. 5, the CF polymer film 115 is formed on the polysilicon film 111 exposed in the trench V₁ to have the thickness T₁, and is formed on the silicon nitride film 112 remaining in the trenches V₂ to have the thickness T₂ smaller than the thickness T₁, by using the C_{X}F_{Y}H_{Z} gas.

Further, as shown in FIG. 6, the etching using the silicon oxide film 113, the resist film 114, and the CF polymer film 115 as a mask (it may be an etching using the silicon oxide film 113 and the CF polymer film 115 as a mask) is performed to etch the CF polymer film 115 and the silicon nitride film 112 remaining in the trenches V₂ so as to expose the polysilicon film 111 in the trenches V₂.

Consequently, in the present embodiment, the over-etching of the polysilicon film 111 in the trench V₁ can be suppressed, and the difference in etching amount of the polysilicon film 111 between the sparse portion R₁ and the dense portion R₂ can be lowered.

Also, in the present embodiment, the CF polymer film 115 is formed by using the C_{X}F_{Y}H_{Z} gas that satisfies the conditions of 0<Y<2X and 0≦Z≦4 in the process in FIG. 5. This makes it possible to effectively suppress the over-etching of the polysilicon film 111 in the trench V₁ at the time of the etching in FIG. 6. This can also provide advantages that the fifth film 115 is easily formed, the fifth film 115 having good quality can be formed, and the like.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A method of manufacturing a semiconductor device on a semiconductor substrate, the method comprising:
forming a first film over the semiconductor substrate, a second film on the first film, a third film on the second film, and a fourth film on the third film;
patterning the fourth film to form a sparse portion in which patterns of the fourth film are sparse and a dense portion in which the patterns of the fourth film are dense;
etching the third film by using the patterns of the fourth film as a mask;
etching the second film by using the patterns of the third and fourth films as a mask so as to expose the first film between the patterns in the sparse portion, and so as to partially remove the second film between the patterns in the dense portion so that the second film between the patterns remains;
forming a fifth film on the first film exposed in the sparse portion to have a first thickness, and on the second film remaining in the dense portion to have a second thickness smaller than the first thickness by using a C_{X}F_{Y}H_{Z} gas, where X, Y, and Z are integers of zero or more and satisfy 0<Y<2X and 0≦Z≦4;
etching the fifth film and the second film remaining between the patterns in the dense portion so as to expose the first film between the patterns in the dense portion; and
removing the fifth film remaining after the etching of the second film between the patterns in the dense portion.

2. The method of claim 1, wherein the fifth film is a polymer film containing carbon and fluorine.

3. The method of claim 1, wherein
the patterns of the fourth film form a line pattern having a predetermined line width and a predetermined space width in each of the sparse and dense portions,
the space width in the sparse portion is equal to or greater than 200 nm, and
the space width in the dense portion is equal to or smaller than 200 nm.

4. The method of claim 1, further comprising:
etching the first film by using the second film as a mask, after the fifth film is removed; and
removing the second film after the etching of the first film.

5. The method of claim 1, further comprising:
etching the first film by using the second and third films as a mask, after the fifth film is removed; and
removing the second and third films after the etching of the first film.

6. The method of claim 1, wherein
the first film is an electrode material formed on the semiconductor substrate via an insulating film, and
the insulating film and the electrode material are used for forming a gate insulator and a gate electrode, respectively.

7. The method of claim 1, wherein
the first film is an electrode material formed on the semiconductor substrate via an insulating film,
the insulating film and the electrode material in the dense portion are used for forming a gate insulator and a floating gate of a memory cell transistor, respectively, and
the insulating film and the electrode material in the sparse portion are used for forming a gate insulator and a part of a gate electrode of a select transistor, respectively.

8. The method of claim 1, wherein
the fifth film and the second film remaining between the patterns in the dense portion are etched so that the fifth film remains between the patterns in the sparse portion until the first film is exposed in the dense portion.

9. The method of claim 1, wherein
the fifth film is formed so that portions of the fifth film formed on the patterns in the dense portion does not contact one another.

10. The method of claim 1, wherein the C_{X}F_{Y}H_{Z} gas is a C₄F₆ gas, a C₅F₈ gas, or a CH₃F gas.

11. A method of manufacturing a semiconductor device on a semiconductor substrate, the method comprising:
forming a first film over the semiconductor substrate, a second film on the first film, a third film on the second film, and a fourth film on the third film;
patterning the fourth film to form a sparse portion in which patterns of the fourth film are sparse and a dense portion in which the patterns of the fourth film are dense;
etching the third film by using the patterns of the fourth film as a mask, and removing the fourth film after the etching of the third film;
etching the second film by using the patterns of the third film as a mask so as to expose the first film between the patterns in the sparse portion, and so as to partially remove the second film between the patterns in the dense portion so that the second film between the patterns remains;
forming a fifth film on the first film exposed in the sparse portion to have a first thickness, and on the second film remaining in the dense portion to have a second thickness smaller than the first thickness by using a C_{X}F_{Y}H_{Z} gas, where X, Y, and Z are integers of zero or more and satisfy 0<Y<2X and 0≦Z≦4;
etching the fifth film and the second film remaining between the patterns in the dense portion so as to expose the first film between the patterns in the dense portion; and
removing the fifth film remaining after the etching of the second film between the patterns in the dense portion.

12. The method of claim 11, wherein the fifth film is a polymer film containing carbon and fluorine.

13. The method of claim 11, wherein
the patterns of the fourth film form a line pattern having a predetermined line width and a predetermined space width in each of the sparse and dense portions,
the space width in the sparse portion is equal to or greater than 200 nm, and
the space width in the dense portion is equal to or smaller than 200 nm.

14. The method of claim 11, further comprising:
etching the first film by using the second film as a mask, after the fifth film is removed; and
removing the second film after the etching of the first film.

15. The method of claim 11, further comprising:
etching the first film by using the second and third films as a mask, after the fifth film is removed; and
removing the second and third films after the etching of the first film.

16. The method of claim 11, wherein
the first film is an electrode material formed on the semiconductor substrate via an insulating film, and
the insulating film and the electrode material are used for forming a gate insulator and a gate electrode, respectively.

17. The method of claim 11, wherein
the first film is an electrode material formed on the semiconductor substrate via an insulating film,
the insulating film and the electrode material in the dense portion are used for forming a gate insulator and a floating gate of a memory cell transistor, respectively, and
the insulating film and the electrode material in the sparse portion are used for forming a gate insulator and a part of a gate electrode of a select transistor, respectively.

18. The method of claim 11, wherein
the fifth film and the second film remaining between the patterns in the dense portion are etched so that the fifth film remains between the patterns in the sparse portion until the first film is exposed in the dense portion.

19. The method of claim 11, wherein
the fifth film is formed so that portions of the fifth film formed on the patterns in the dense portion does not contact one another.

20. The method of claim 11, wherein the C_{X}F_{Y}H_{Z} gas is a C₄F₆ gas, a C₅F₈ gas, or a CH₃F gas.
